(19) United States
(12) Patent Application Publication
(10) Pub. No.: US 2026/0293546 A1
(43) Pub. Date: Sep. 24, 2026

(54) METHODS OF USING HIGH ENERGY EXCITED STATE HELIUM RADICALS FOR POST NITRIDATION ANNEAL OR POST OXIDATION ANNEAL

(71) Applicant: Applied Materials, Inc., Santa Clara, CA (US)

(72) Inventors: Wei LIU, San Jose, CA (US); Dimitrios PAVLOPOULOS, Santa Clara, CA (US); Sandip NIYOGI, Oakland, CA (US); Simin ZOU, Santa Clara, CA (US)

(21) Appl. No.: 19/086,340

(22) Filed: Mar. 21, 2025

(51) Int. Cl. H10P 14/60; H01J 37/32

(52) U.S. Cl. CPC H10P 14/6532; H01J 37/321; H01J 37/3244; H01J 37/32816; H10P 14/6339; H10P 14/6522; H10P 14/6526

(57) ABSTRACT

Certain aspect relate to methods for treating materials used in semiconductor manufacturing with high-energy excited-state helium radicals. The method includes curing a substrate stack comprising a dielectric film to form a cured substrate stack by exposing the substrate stack to an excited-state helium radical treatment process. The excited-state helium radical treatment process includes generating an inductively coupled plasma from a process gas comprising helium. The inductively coupled plasma includes at least one excited-state helium radical species. The helium radical treatment process includes contacting the inductively coupled plasma Including the at least one excited-state helium radical species with the substrate stack to cure the substrate stack and form the cured substrate stack, wherein curing the substrate stack is performed at a temperature of 750 degrees Celsius or less.

### TECHNICAL FIELD

Implementations of the present disclosure generally relate to semiconductor manufacturing systems and methods for forming semiconductor devices. More particularly, implementations of the present disclosure relate to methods for treating materials used in semiconductor manufacturing with high-energy excited-state helium radicals.

### BACKGROUND

Rapid thermal processing (RTP) is a semiconductor manufacturing process, which heats semiconductor wafers to extremely high temperatures, for example, temperatures exceeding 750 degrees Celsius, for not more than a few seconds. During cooling, temperatures are slowly reduced to prevent dislocations and wafer breakage due to thermal shock. The rapid heating rates of RTP are often attained by high intensity lamps or lasers. RTP is used for a wide variety of applications in semiconductor manufacturing including dopant activation, thermal oxidation, thermal nitridation, and metal reflow.

Conventional RTP processes generally operate at high temperatures, such as above 750 degrees Celsius. This operating temperature is relatively high, which not only needs a high thermal budget but also limits the application of the RTP to materials that can survive a high processing temperature. Currently, thermal budget requirements are typically 500 degrees Celsius or lower for many applications.

Thus, a need exists for improved methods for injecting energy into films at lower temperatures to meet current thermal budget requirements in semiconductor devices.

### SUMMARY

Implementations of the present disclosure generally relate to semiconductor manufacturing systems and methods for forming semiconductor devices. More particularly, implementations of the present disclosure relate to methods for treating materials used in semiconductor manufacturing with high-energy excited-state helium radicals.

In one aspect, a method for forming a semiconductor device is provided. The method includes curing a substrate stack comprising a dielectric film to form a cured substrate stack by exposing the substrate stack to an excited-state helium radical treatment process. The excited-state helium radical treatment process includes generating an inductively coupled plasma from a process gas comprising helium. The inductively coupled plasma includes at least one excited-state helium radical species. The helium radical treatment process includes contacting the inductively coupled plasma Including the at least one excited-state helium radical species with the substrate stack to cure the substrate stack and form the cured substrate stack, wherein curing the substrate stack is performed at a temperature of 750 degrees Celsius or less.

Implementations may include one or more of the following. The process gas includes helium comprises at least 95% helium. The excited-state helium radical species has an energy of 5 eV or higher. Generating the inductively coupled plasma is performed at a pressure in a range from about 0.1 Torr to about 5 Torr at a radio frequency power in a range from about 5 kW to about 10 kW. The temperature is 500 degrees Celsius or less. The dielectric film is formed by an atomic layer deposition (ALD) process or a chemical vapor deposition (CVD) process. The method further includes exposing the substrate stack to oxygen radicals, nitrogen radicals, or both oxygen radicals and nitrogen radicals prior to curing the substrate stack. Exposing the substrate stack to oxygen radicals, nitrogen radicals, or both oxygen radicals and nitrogen radicals is performed in a first processing volume and curing the substrate stack is performed in a second processing volume. The dielectric film is a silicon-containing dielectric film having a k-value of three or less.

In another aspect, a method for forming a semiconductor device is provided. The method includes exposing a substrate stack to oxygen radicals, nitrogen radicals, or both oxygen radicals and nitrogen radicals to form a nitridized/oxidized substrate stack. The method further includes curing the nitridized/oxidized substrate stack to form a cured substrate stack by exposing the nitridized/oxidized substrate stack to an excited-state helium radical treatment process. The excited-state helium radical treatment process includes generating an inductively coupled plasma from a process gas including helium. The inductively coupled plasma comprises at least one excited-state helium radical species. The excited-state helium radical treatment process further includes contacting the inductively coupled plasma including the at least one excited-state helium radical species with the nitridized/oxidized substrate stack to cure the nitridized/oxidized substrate stack and form the cured substrate stack. Curing the nitridized/oxidized substrate stack is performed at a temperature of 750 degrees Celsius or less.

Implementations may include one or more of the following. The process gas including helium comprises at least 95% helium. The process gas including helium comprises at least 99.995% helium. The excited-state helium radical species has an energy of 5 eV or higher. The excited-state helium radical species has an energy of 19.8 eV or higher. Generating the inductively coupled plasma is performed at a pressure in a range from about 0.1 Torr to about 5 Torr at a radio frequency power in a range from about 5 kW to about 10 kW. The temperature is 500 degrees Celsius or less. The substrate stack includes a dielectric film formed by an atomic layer deposition (ALD) process or a chemical vapor deposition (CVD) process. Exposing the substrate stack to oxygen radicals, nitrogen radicals, or both oxygen radicals and nitrogen radicals and curing the nitridized/oxidized substrate stack are performed in a first processing volume. Exposing the substrate stack to oxygen radicals, nitrogen radicals, or both oxygen radicals and nitrogen radicals is performed in a first processing volume and curing the nitridized/oxidized substrate stack is performed in a second processing volume. The method further includes transferring the nitridized/oxidized substrate stack from the first processing volume to the second processing volume without exposing the nitridized/oxidized substrate stack to ambient. The substrate stack includes a silicon-containing dielectric film having a k-value of three or less. The silicon-containing dielectric film is a silicon oxide film, a SiOC film, or a silicon nitride film. The silicon-containing dielectric film has a lower k-value and increased hardness after curing the nitridized/oxidized substrate stack.

In yet another aspect, a method for forming a semiconductor device is provided. The method includes exposing a substrate stack to oxygen radicals, nitrogen radicals, or both oxygen radicals and nitrogen radicals to form a nitridized/oxidized substrate stack. The method further includes curing the nitridized/oxidized substrate stack to form a cured substrate stack by exposing the nitridized/oxidized substrate stack to an excited-state helium radical treatment process. The excited-state helium radical treatment process includes introducing a process gas including helium into a gas injection channel of a plasma source. The excited-state helium radical treatment process further includes generating an inductively coupled plasma within the gas injection channel with an induction coil positioned proximate a sidewall of the plasma source and horizontally overlapping the gas injection channel, wherein the inductively coupled plasma comprises at least one excited-state helium radical species. The excited-state helium radical treatment process further includes contacting the inductively coupled plasma including the at least one excited-state helium radical species with the nitridized/oxidized substrate stack to cure the nitridized/oxidized substrate stack and form the cured substrate stack. Curing the nitridized/oxidized substrate stack is performed at a temperature of 750 degrees Celsius or less.

Implementations may include one or more of the following. Exposing the substrate stack to oxygen radicals, nitrogen radicals, or both oxygen radicals and nitrogen radicals and curing the nitridized/oxidized substrate stack are performed in a first processing volume. Exposing the substrate stack to oxygen radicals, nitrogen radicals, or both oxygen radicals and nitrogen radicals is performed in a first processing volume and curing the nitridized/oxidized substrate stack is performed in a second processing volume. The method further includes transferring the nitridized/oxidized substrate stack from the first processing volume to the second processing volume without exposing the nitridized/oxidized substrate stack to ambient. The substrate stack includes a dielectric film formed by an atomic layer deposition (ALD) process or a chemical vapor deposition (CVD) process. The substrate stack includes a silicon-containing dielectric film having a k-value of three or less. The silicon-containing dielectric film is a silicon oxide film, a SiOC film, or a silicon nitride film. The silicon-containing dielectric film has a lower k-value and increased hardness after curing the nitridized/oxidized substrate stack. Exposing the substrate stack to oxygen radicals, nitrogen radicals, or both oxygen radicals and nitrogen radicals includes introducing a process gas including nitrogen into the gas injection channel; generating a nitrogen plasma within the gas injection channel with the induction coil, wherein the nitrogen plasma comprises at least one nitrogen radical species; delivering the nitrogen plasma from the plasma source to a processing volume coupled therewith; and processing the substrate stack within the processing volume. Processing the substrate stack includes contacting the nitrogen plasma including the at least one nitrogen radical species with the substrate stack. Exposing the substrate stack to oxygen radicals, nitrogen radicals, or both oxygen radicals and nitrogen radicals, includes introducing a process gas including oxygen into the gas injection channel of the plasma source; generating an oxygen plasma within the gas injection channel with the induction coil, wherein the oxygen plasma comprises at least one oxygen radical species; delivering the oxygen plasma from the plasma source to a processing volume coupled therewith; and processing the substrate stack within the processing volume. Processing the substrate stack includes contacting the oxygen plasma including the at least one oxygen radical species with the substrate stack. The gas injection channel is defined between a gas injection insert and the sidewall of the plasma source. The process gas including helium comprises at least 95% helium. The process gas including helium comprises at least 99.995% helium. The excited-state helium radical species has an energy of 5 eV or higher. The excited-state helium radical species has an energy of 19.8 eV or higher. Generating the inductively coupled plasma is performed at a pressure in a range from about 0.1 Torr to about 5 Torr at a radio frequency power in a range from about 5 kW to about 10 kW. The temperature is 500 degrees Celsius or less. The temperature is 400 degrees Celsius or less.

In yet another aspect, a plasma processing method for forming a semiconductor device is provided. The plasma process method includes exposing a substrate stack including a dielectric layer to an excited-state helium radical treatment process. The excited-state helium radical treatment process includes introducing a process gas including helium into a gas injection channel of a plasma source. The excited-state helium radical treatment process further includes generating an inductively coupled plasma within the gas injection channel with an induction coil positioned proximate a sidewall of the plasma source and horizontally overlapping the gas injection channel. The inductively coupled plasma comprises at least one helium radical species. The excited-state helium radical treatment process further includes contacting the inductively coupled plasma including the at least one helium radical species with the substrate stack to densify the dielectric layer and form a densified dielectric layer. The excited-state helium radical treatment process is performed at a temperature of 750 degrees Celsius or less. The plasma processing method further includes exposing the densified dielectric layer to a nitrogen radical species to incorporate nitrogen into the densified dielectric layer to form a nitrogen-containing dielectric layer.

Implementations may include one or more of the following. Exposing the nitrogen-containing dielectric layer to a second excited-state helium radical treatment process. The dielectric layer is a SiOC film and the nitrogen and silicon-containing dielectric film is a SiCON film. The nitrogen radical species are generated from a second process gas including nitrogen gas and argon gas. The nitrogen radical species are generated form a second process gas including ammonia gas and argon gas. Exposing the densified dielectric layer to the nitrogen radical species, comprises introducing a second process gas including nitrogen into the gas injection channel; generating a nitrogen plasma within the gas injection channel with the induction coil, wherein the nitrogen plasma comprises at least one nitrogen radical species; delivering the nitrogen plasma from the plasma source to a processing volume coupled therewith; and processing the substrate stack within the processing volume. Processing the substrate stack includes contacting the nitrogen plasma including the at least one nitrogen radical species with the densified dielectric layer to form the nitrogen and silicon-containing dielectric film. The gas injection channel is defined between a gas injection insert and the sidewall of the plasma source. The process gas including helium comprises at least 95% helium. The process gas including helium comprises at least 99.995% helium. The excited-state helium radical species has an energy of 5 eV or higher. The excited-state helium radical species has an energy of 19.8 eV or higher. Generating the inductively coupled plasma is performed at a pressure in a range from about 0.1 Torr to about 5 Torr at a radio frequency power in a range from about 5 kW to about 10 kW. The temperature is 500 degrees Celsius or less. The temperature is 400 degrees Celsius or less.

In yet another aspect, a plasma processing system is provided. The system includes a processing chamber defining a processing volume; a plasma source; a gas injection channel; an induction coil positioned proximate to a sidewall of the plasma source and horizontally overlapping the gas injection channel; and a system controller. The system controller includes a memory for storing computer readable instructions and a processor coupled to the memory, the processor configured by the computer readable instructions that when executed by the processor perform a plurality of operations including an excited-state helium radical treatment process. The excited-state helium radical treatment process includes introducing a process gas into the gas injection channel; generating an inductively coupled plasma within the gas injection channel with the induction coil, wherein the plasma comprises at least one helium radical species; delivering the plasma from the plasma source to the processing volume; and processing a substrate stack within the processing volume, the substrate stack including a dielectric layer. Processing the substrate stack includes contacting the plasma including the at least one helium radical species with the dielectric layer, wherein the excited-state helium radical treatment process is performed at a temperature of 750 degrees Celsius or less.

Implementations may include one or more of the following. The plurality of operations further include exposing the dielectric layer to oxygen radicals, nitrogen radicals, or both oxygen radicals and nitrogen radicals. Exposing the dielectric layer to oxygen radicals, nitrogen radicals, or both oxygen radicals and nitrogen radicals occurs prior to the excited-state helium radical treatment process. Exposing the dielectric layer to oxygen radicals, nitrogen radicals, or both oxygen radicals and nitrogen radicals occurs after the excited-state helium radical treatment process. A gas injection insert disposed within the plasma source, wherein the gas injection channel is defined between the gas injection insert and the sidewall of the plasma source. The process gas including helium comprises at least 95% helium. The process gas including helium comprises at least 99.995% helium. The excited-state helium radical species has an energy of 5 eV or higher. The excited-state helium radical species has an energy of 19.8 eV or higher. Generating the inductively coupled plasma is performed at a pressure in a range from about 0.1 Torr to about 5 Torr at a radio frequency power in a range from about 5 kW to about 10 kW. The temperature is 500 degrees Celsius or less. The temperature is 400 degrees Celsius or less.

In yet another aspect, a non-transitory computer readable medium has stored thereon instructions, which, when executed by a processor, causes the process to perform operations of the above apparatus and/or method.

### BRIEF DESCRIPTION OF THE DRAWINGS

So that the manner in which the above recited features of the present disclosure can be understood in detail, a more particular description of the disclosure, briefly summarized above, may be had by reference to implementations, some of which are illustrated in the appended drawings. It is to be noted, however, that the appended drawings illustrate only exemplary implementations and are therefore not to be considered limiting of its scope, and may admit to other equally effective implementations.

FIG. 1 is a schematic view of a system in accordance with one or more implementations described herein.

FIG. 2 is a flow diagram depicting a method of performing an excited-state helium radical treatment process in accordance with one or more implementations described herein.

FIG. 3 illustrates a view of a stage of forming a semiconductor structure in accordance with one or more implementations described herein.

FIG. 4 is a flow diagram depicting another method of performing an excited-state helium radical treatment process in accordance with one or more implementations described herein.

FIGS. 5A-5C illustrate views of various stages of forming a semiconductor structure in accordance with one or more implementations described herein.

FIG. 6 is a flow diagram depicting another method of performing an excited-state helium radical treatment process in accordance with one or more implementations described herein.

FIGS. 7A-7B illustrate views of various stages of forming a semiconductor structure in accordance with one or more implementations described herein.

FIG. 8 is a flow diagram depicting another method of performing an excited-state helium radical treatment process in accordance with one or more implementations described herein.

FIG. 9 is a flow diagram depicting another method of performing an excited-state helium radical treatment process in accordance with one or more implementations described herein.

To facilitate understanding, identical reference numerals have been used, where possible, to designate identical elements that are common to the figures. It is contemplated that elements and features of one implementation may be beneficially incorporated in other implementations without further recitation.

### DETAILED DESCRIPTION

Implementations of the present disclosure generally relate to semiconductor manufacturing systems and methods for forming semiconductor devices. More particularly, implementations of the present disclosure relate to methods for treating materials used in semiconductor manufacturing with high-energy excited-state helium radicals.

Traditional post nitridation anneal (PNA) processes and post oxidation anneal (POA) processes use RTP high temperature anneal performed at temperatures of about 750 degrees Celsius or greater, which are too high for many device integration schemes. In one or more implementations described herein, which can be combined with other implementations, a high-density excited-state helium radical (He*) treatment process is provided. The high-density helium radical treatment process described herein provides a high flux of highly excited-state He* radicals, which can be used to cure a film post nitridation and/or post oxidation at lower temperatures. The high-density excited-state He* radical treatment process provides several advantages. The high-density excited-state He* radical treatment process provides a high-energy treatment, which is conformal as opposed to directional. In addition, helium has the smallest atomic radius and is highly diffusive. Further, helium is chemically inert and can be used to treat all types of films at low temperatures. In addition, although the high-density helium radical treatment process described herein is performed on low-k dielectric materials, the high-density helium radical treatment process may be used to treat any type of material that is typically treated with high temperature anneal processes. For example, high-density helium radical treatment process may be used in place of RTP for dopant activation, densification of ALD films and/or other low quality CVD films, silicide and barrier metal formation, chemical vapor deposition, and other steps in semiconductor manufacturing.

Not to be bound by theory, but it is believed that in gas phase the de-excitation of excited-state He* radicals produces photons in DUV / EUV range; in solid films, the de-excitation of the excited-state He* radicals can transfer energy to other atoms in the film. The energy can be used to repair the damage caused during prior nitridation and oxidation processes. For example, the energy can be used to cure the imperfect bonding, for example, N-O metastable bonds, in post nitridation oxide films.

In one or more implementations, which can be combined with other implementations, a plasma nitridation process is performed to introduce nitrogen into a film followed by a high-density excited-state He* radical treatment process to cure the imperfect bonding and improve the electrical performance of the nitrogen treated film. The plasma nitridation process and the high-density excited-state He* radical treatment process can be performed in the same chamber with an optional purge process in between. The plasma nitridation process and the high-density excited-state He* radical treatment process can be performed in separate chambers to reduce cross contamination. The nitridation chamber may be on the same cluster tool as the helium radical treatment chamber so the substrate can be transferred between the chambers without exposure to the ambient environment.

In one or more implementations, which can be combined with other implementations, a plasma oxidation process is performed to oxidize a film followed by a high-density excited-state He* radical treatment process to cure the imperfect bonding and improve the electrical performance of the oxidized film. The plasma oxidation process and the high-density excited-state He* radical treatment process can be performed in the same chamber with an optional purge process in between processes. The plasma oxidation process and the high-density excited-state He* radical treatment process can be performed in separate chambers to reduce cross contamination. The oxidation chamber may be on the same cluster tool as the helium radical treatment chamber so the substrate can be transferred between the chambers without exposure to the ambient environment.

In one or more implementations, which can be combined with other implementations, a remote plasma oxidation (RPO) process is performed to oxidize a film followed by a high-density excited-state He* radical treatment process to cure the imperfect bonding and improve the electrical performance of the treated film. The RPO process and the high-density excited-state He* radical treatment process are performed in separate chambers to reduce cross contamination. The RPO chamber may be on the same cluster tool as the helium radical treatment chamber so the substrate can be transferred between the chambers without exposure to the ambient environment.

In one or more implementations, which can be combined with other implementations, a film is exposed to a high-density excited-state He* radical treatment process to densify the film prior to additional processing.

In one or more implementations, which can be combined with other implementations, a film is exposed to a high-density excited-state He* radical treatment process to densify the film followed by a nitrogen/argon plasma treatment to incorporate nitrogen into the densified film. Optionally the nitrogen treated densified film can be exposed to a second high-density excited-state He* radical treatment process to cure the imperfect bonding and improve the electrical performance of the treated film.

In one or more implementations, which can be combined with other implementations, a decoupled plasma nitridation (DPN) process is performed to introduce nitrogen into a film followed by a high-density excited-state He* radical treatment process to cure the imperfect bonding and improve the electrical performance of the nitrogen treated film. The DPN process and the high-density excited-state He* radical treatment process can be performed in the same chamber with an optional purge process in between. The DPN process and the high-density excited-state He* radical treatment process can be performed in separate chambers to reduce cross contamination. The DPN chamber may be on the same cluster tool as the helium radical treatment chamber so the substrate can be transferred between the chambers without exposure to the ambient environment.

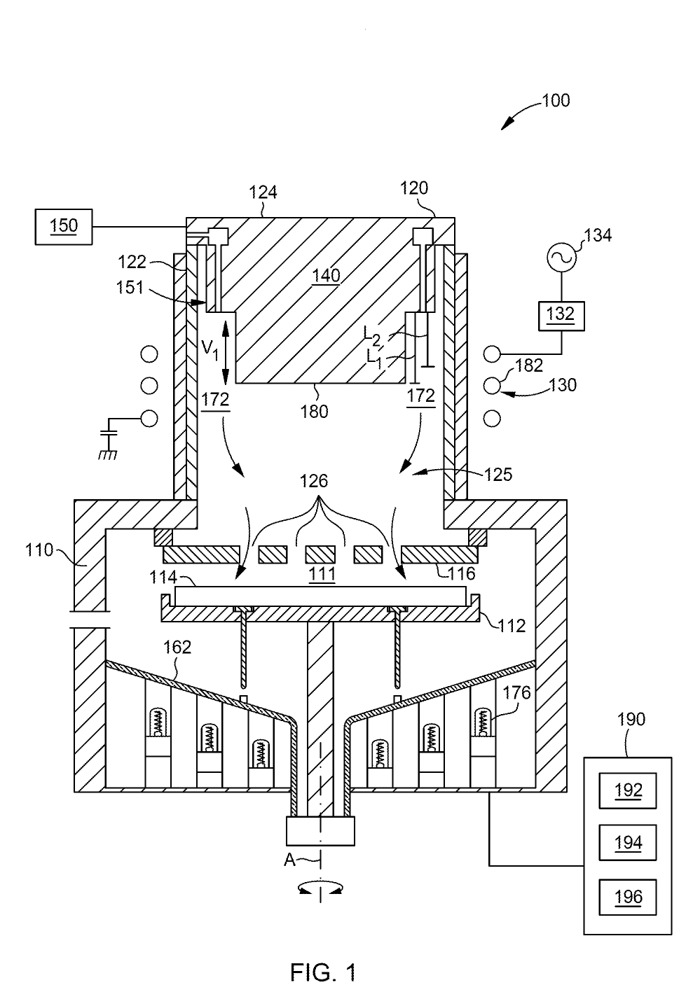

FIG. 1 is a schematic view of a plasma processing system, in accordance with one or more implementations of the present disclosure. The plasma processing system 100 includes a processing chamber 110 and a plasma source 120 (e.g., a remote plasma source) coupled with the processing chamber 110. The processing chamber 110 also includes a substrate support 112 operable to hold a substrate 114. The processing chamber 110 defines a processing volume 111 in between the plasma source 120 and the substrate support 112. Substrate support 112 can be proximate one or more heat sources, for example, a plurality of lamps 176, which provide heat to a substrate during processing of the substrate in the processing chamber 110. The plurality of lamps 176 are disposed between the window 162 and a bottom wall of the processing chamber 110. The substrate support 112 is disposed between a separation grid 116, which is optional, and the window 162. In other embodiments, the plurality of lamps 176 are replaced by one or more resistive heaters or the electrostatic chuck heater in the substrate support 112.

The plasma source 120 includes a dielectric sidewall 122. The plasma source 120 includes a top cover 124. The dielectric sidewall 122 and the top cover 124, integrated with a gas injection insert 140 define a plasma source interior 125. The dielectric sidewall 122 can include any suitable dielectric material, such as quartz. An induction coil 130 is disposed proximate, for example, adjacent to, the dielectric sidewall 122 about the plasma source 120. The induction coil 130 is coupled to an RF power generator 134 through any suitable matching network 132. Feed gases are introduced to the plasma source interior 125 from a gas supply 150. When the induction coil 130 is energized with RF power from the RF power generator 134, a plasma is generated in the plasma source 120. To increase efficiency, the plasma processing system 100 includes a gas injection insert 140 disposed in the plasma source interior 125. The gas injection insert 140 includes one or more gas injection channels 151. The gas injection channels 151 provide the process gas to the plasma source interior 125 through an active zone 172, where due to enhanced confinement of hot electrons, a reaction between hot electrons and the feed gas occurs. The induction coil 130 at least partially horizontally overlaps with the gas injection channels 151.

A plasma can be generated in the plasma source 120 (e.g., in a plasma generation region) by the induction coil 130 and targeted particles flow from the plasma source 120 to the surface of the substrate 114 through holes 126 provided in a separation grid 116 that separates the plasma source 120 from the processing chamber 110 (a downstream region). The separation grid 116 is configured to separate the processing volume 111 from plasma charged particles (ions and electrons), which recombine on the separation grid 116, so that only neutral plasma species can pass through the separation grid 116 into the processing volume 111 of the processing chamber 110.

In some implementations, the induction coil 130 is aligned with the active zone 172 in such a way that a top turn of the induction coil 130 is above a bottom edge 180 or bottom surface of the gas injection insert 140 and operates substantially in the active zone 172 of the inner volume, while a bottom turn of the induction coil 130 is below the bottom edge 180 and operates substantially outside the active zone 172. A center of the induction coil 130 is substantially aligned with the bottom edge 180. Within these boundaries, the position of the induction coil 130 can be adjusted for a targeted performance.

In some implementations, the bottom edge 180 is aligned with a portion of induction coil 130 (e.g., coil loop 182) along axis 184 by utilizing a suitably sized gas injection insert 140 (and top cover 124, which may be a preformed part of the gas injection insert 140) to form the plasma source 120. Alternatively, the bottom edge 180 can be movable along a vertical direction V₁ relative to plasma source 120 while a remainder portion of the gas injection insert 140 is static (e.g., fixed) as part of plasma source 120, in order to provide alignment of the bottom edge 180 with a portion of the induction coil 130. For example, a mechanism can be coupled with any suitable portion of the gas injection insert 140 to adjust a position of the bottom edge 180 such that a portion of the gas injection insert 140 having a first length (L₁) is adjusted to a second length (L₂).

The plasma processing system 100 further includes a system controller 190 for controlling processes performed by the plasma processing system 100. The system controller 190 can be any type of controller used in an industrial setting, such as a programmable logic controller (PLC). The system controller 190 includes a processor 192, a memory 194, and input/output (I/O) circuits 196. The system controller 190 can further include one or more of the following components (not shown), such as one or more power supplies, clocks, communication components (e.g., network interface card), and user interfaces typically found in controllers for semiconductor equipment.

The memory 194 can include non-transitory memory. The non-transitory memory can be used to store the computer readable instructions, programs and settings described below. The memory 194 can include one or more readily available types of memory, such as read only memory (ROM) (e.g., electrically erasable programmable read-only memory (EEPROM), flash memory, floppy disk, hard disk, or random access memory (RAM) (e.g., non-volatile random access memory (NVRAM).

The processor 192 is coupled to the memory. The processor 192 is configured by the computer readable instructions or programs stored in the memory 194 that when executed by the processor 192 perform a plurality of operations, for example, the plurality of operations of the method 200, the method 400, the method 600, the method 800, or the method 900. During execution of these instructions or programs, the system controller 190 can communicate to I/O devices through the I/O circuits 196. For example, during execution of these programs and communication through the I/O circuits 196, the system controller 190 can control outputs (e.g., the plasma source 120, the RF power generator 134, gas delivery from the gas supply 150). The memory 194 can further include various operational settings used to control the plasma processing system 100. For example, the settings can include temperature and pressure settings as well as settings to control gas delivery from the gas sources described herein.

Methods of using the plasma processing system 100 to treat a substrate using high-density helium radicals are also provided. The high-density helium radical treatment process can be used in low temperature applications, for example, temperatures of 750°C or less, or 500°C or less, or 400°C or less, or 300°C or less, or 200°C or less, or 100°C or less to cure imperfect bonding. In certain implementations, the substrate includes a dielectric material. The dielectric material can be a low-k dielectric material or a high-k dielectric material. In some implementations, the low-k material of the substrate includes a silicon-containing dielectric material such as silicon oxide, silicon nitride, silicon oxynitride (SiON), silicon oxycarbide (SiOC), silicon oxycarbonitride (SiOCN), or a combination thereof. In some implementations, the high-k dielectric material of the substrate includes a metal oxide insulator such as Al2O3, HfO2, ZrO2, HfZrO4, TiO2, or a combination thereof.

In some implementations, the plasma processing system 100 may be used to perform a plasma nitridation process on the substrate with high-density nitrogen radicals. In some implementations, the plasma nitridation process may form one or more nitric layers on the substrate. The plasma nitridation process can be followed by a high-density helium radical treatment process to repair damage caused by the plasma nitridation process. Both the plasma nitridation process and the helium radical treatment process can be performed in the same processing system, for example, the plasma processing system 100.

In some implementations, the plasma processing system 100 may be used to perform a plasma oxidation process on the substrate with high-density oxygen radicals. In some implementations, the plasma oxidation process may decrease impurities and oxygen vacancies in the substrate. The plasma oxidation process can be followed by a high-density helium radical treatment process to repair damage caused by the plasma oxidation process. Both the plasma oxidation process and the helium radical treatment process can be performed in the same processing system, for example, the plasma processing system 100.

In some implementations, the plasma processing system 100 may be used to sequentially perform both the plasma nitridation process and the plasma oxidation process on the substrate. In certain implementations, the plasma nitridation process may be performed first followed by the plasma oxidation process. In other implementations, the plasma oxidation process may be performed first followed by the plasma nitridation process. In yet other implementations, the plasma oxidation and nitridation processes may be performed simultaneously. The plasma oxidation and nitridation processes can be followed by a high-density helium radical treatment process to repair damage caused by the plasma oxidation and nitridation processes. The plasma oxidation and nitridation processes and the helium radical treatment process can be performed in the same processing system, for example, the plasma processing system 100.

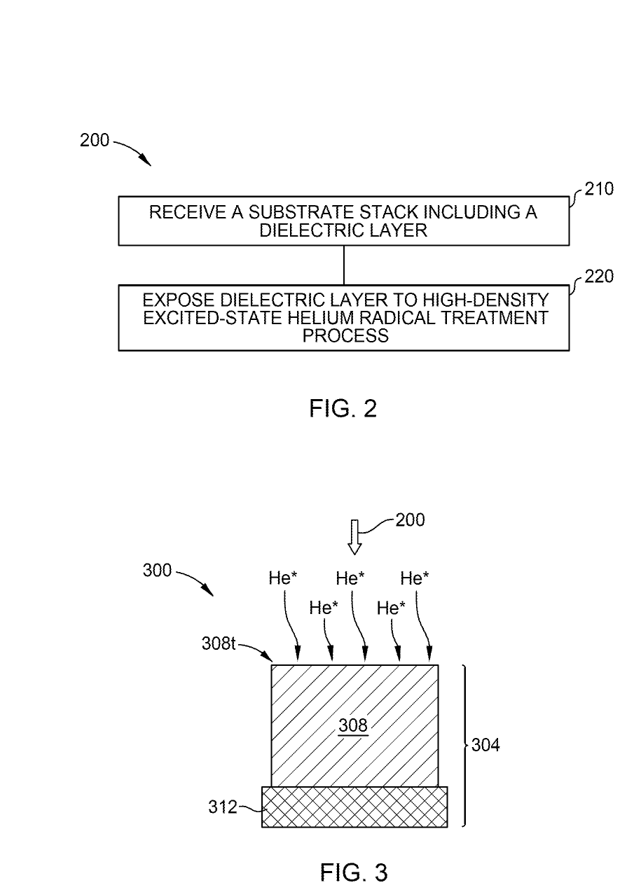

FIG. 2 is a flow diagram depicting a method 200 of treating a high-k dielectric layer with helium radicals in accordance with one or more implementations of the present disclosure. FIG. 3 illustrates views of various stages of forming a semiconductor structure in accordance with one or more implementations described herein. Although FIG. 3 is described in relation to the method 200, the structure disclosed in FIG. 3 is not limited to the method 200, but instead may stand alone as structures that are independent of the method 200. Similarly, although the method 200 is described in relation to FIG. 3, the method 200 is not limited to the structure disclosed in FIG. 3 but instead may stand alone independent of the structures disclosed in FIG. 3. It should be understood that FIG. 3 illustrates only partial schematic views of a semiconductor device structure 300, and the semiconductor device structure 300 may contain any number of transistor sections and additional materials having aspects as illustrated in the figures. It should also be noted that although the method 200 illustrated in FIG. 2 is described sequentially, other process sequences that include one or more operations that have been omitted and/or added, and/or has been rearranged in another desirable order, fall within the scope of the implementations of the disclosure provided herein.

At operation 210, a substrate stack 304 is received. The substrate stack 304 may be positioned on the substrate support 112 of the plasma processing system 100 shown in FIG. 1. The substrate stack 304 may be or include the substrate 114 shown in FIG. 1. Referring to FIG. 3, the substrate stack 304 includes a dielectric layer 308. The dielectric layer 308 can be a low-k dielectric layer. The low-k dielectric layer can be a silicon-containing dielectric layer. The substrate stack 304 may further include a substrate 312, for example a polysilicon substrate, on which the dielectric layer 308 is formed. The substrate stack 304 can include additional layers and/or features, which are not shown for the sake of brevity.

The dielectric layer 308 is formed on or over the substrate 312 as shown in FIG. 3. The dielectric layer 308 has a top surface 308t. In one or more implementations where the dielectric layer 308 is a low-k dielectric layer, the dielectric layer 308 is fabricated from any suitable dielectric material having a k-value of 3.9 or less, such as silicon oxide, silicon nitride, silicon oxynitride (SiON), silicon oxycarbide (SiOC), silicon oxycarbonitride (SiOCN), or a combination thereof. In some implementations, the dielectric layer 308 is a multi-layer stack including at least one layer of low-k dielectric material. The dielectric layer 308 has a k-value of 3.9 or less, for example, a k-value in a range from 2 to 3. The dielectric layer 308 can have a thickness greater than or equal to 10 Angstroms. The dielectric layer 308 can have a thickness in a range from about 10 Angstroms to about 500 Angstroms. The dielectric layer 308 can be formed on or over the substrate 312 by any suitable process. In one or more implementations, the dielectric layer 308 is formed by a chemical vapor deposition (CVD) process, a plasma-enhanced CVD (PECVD) process, or an atomic layer deposition (ALD) process. The CVD process can be performed at a deposition temperature less than 500 °C, for example, in a range from about 150 °C to about 350 °C or in a range from about 250 °C to about 350 °C.

In one or more implementations where the dielectric layer 308 is a high-k dielectric layer, the dielectric layer 308 is fabricated from any suitable dielectric material having a k-value of 20 or higher, such as zirconium oxide (ZrO₂), aluminum oxide (Al₂O₃),titanium dioxide (TiO₂), hafnium dioxide (HfO₂), or hafnium zinc oxide (HfZO) (combination of HfO and ZrO2). In some implementations, the dielectric layer 308 is a multi-layer stack including at least one layer of high-k dielectric material. In one implementation, the dielectric layer 308 includes a ZrO₂ layer and a silicon nitride (SiN) layer. In another implementation, the dielectric layer 308 includes a layer of high-k dielectric material sandwiched between two low-k dielectric layers. The dielectric layer 308 has a k-value ranging from about 20 to about 50. The dielectric layer 308 can have a thickness greater than or equal to 50 Angstroms. The dielectric layer 308 can have a thickness in a range from about 50 Angstroms to about 500 Angstroms. The dielectric layer 308 can be formed on or over the substrate 312 by any suitable process. In one or more implementations, the dielectric layer 308 is formed by an atomic layer deposition (ALD) process. The ALD process can be performed at a deposition temperature less than 500 °C, for example, in a range from about 150 °C to about 350 °C or in a range from about 250 °C to about 350 °C.

At operation 220, the substrate stack 304 including the dielectric layer 308 is exposed to a high-density excited-state helium radical treatment process as is shown in FIG. 3. Exposure to the high-density excited-state helium radical treatment process may cure imperfect bonding and densify the dielectric layer 308. During the excited-state helium radical treatment process of operation 220, helium (He) source gas is introduced to a plasma processing source to generate excited-state helium radicals. The excited-state helium radical species has an energy of 5 eV or higher. The excited-state helium radicals can have an energy of 19.8 eV or higher. Not to be bound by theory but it is believed that during movement of the excited-state helium radicals from a higher excited-state to a lower state energy is transferred into the atoms/bonds of the film to be treated. The excited-state helium radicals having an energy of 19.8 eV is believed to be stable enough to have a longer lifetime than the diffusion needed. The flow rate of helium can be in a range from about 100 sccm to about 2000 sccm. In one or more embodiments, pure helium or substantially pure helium is used. In one or more embodiments, pure helium has a purity of at least 99.995%. In one or more other embodiments, pure helium has a purity of a least 95%, for example in a range from at least 95% to less than 99.995%. In other embodiments, it is contemplated that the helium source gas may be mixed with an inert gas, for example, argon. During the excited-state helium radical treatment process of operation 220, the temperature in the process chamber can be about 750 °C or less, 650 °C or less, 550 °C or less, 450 °C or less, 350 °C or less, for example, in a range from about 100 °C to about 500 °C, or in a range from about 200 °C to about 400 °C. The pressure in the process chamber can be in a range from about 0.1 Torr to about 5 Torr, or in a range from about 0.5 Torr to about 1 Torr. The radio frequency power can be in a range from about 1 kW to about 10 kW, or in a range from about 5 kW to about 10 kW, or in a range from about 8 kW to about 10 kW.

Referring to FIG. 1, when utilizing the plasma processing system 100 disclosed herein, a plasma including the helium radicals is formed in the active zone 172 of the plasma source interior 125. For example, a first process gas comprising, consisting of, or consisting essentially of helium can be introduced via the gas injection channels 151 to form the plasma including the helium radicals. In one or more embodiments, the first process gas comprises at least 95% helium, for example, at least 95% helium and less than 99.995% helium. In one or more other embodiments, the first process gas comprises at least 99.995% helium. In one or more embodiments, the first process gas is free from or substantially free from inert gases. Not to be bound by theory but it is believed that the inclusion of additional gases such as inert gases prevents the helium radicals from achieving a high-excited state. The plasma can be an inductively coupled plasma generated within the gas injection channels 151 by the induction coil 130. The first process gas can further include an inert gas, for example argon. In some implementations, the first process gas can be introduced to the active zone 172 of the plasma source interior 125 at a first process gas flow rate in a range from about 100 standard cubic centimeters per minute (sccm) to about 20,000 sccm, or from about 100 sccm to about 10,000 sccm, or from about 200 sccm to about 5,000 sccm, or from about 500 sccm to about 1,000 sccm. In some implementations, the helium radical can be introduced for a period in a range from about 10 seconds (s) to about 700 s, for example, from about 60 s to about 600 s, from about 300 s to about 600 s, or from about 120 s to about 300 s. The plasma including the helium radicals is delivered from the plasma source interior 125 to the processing volume 111 where the helium radicals contact the dielectric layer 308.

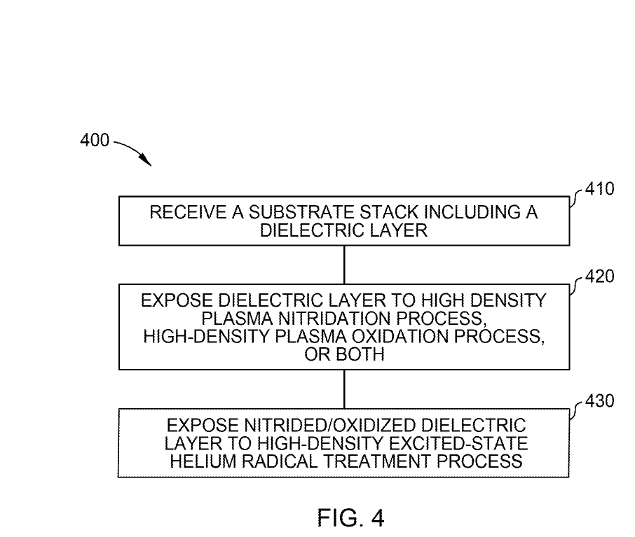

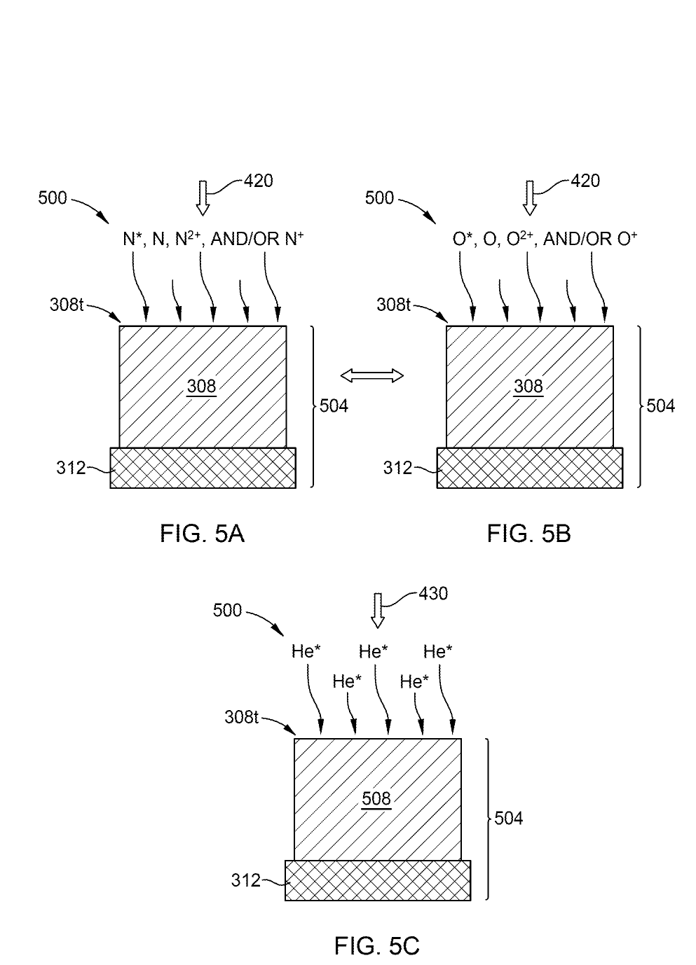

FIG. 4 is a flow diagram depicting a method 400 of treating a dielectric layer with helium radicals in accordance with one or more implementations of the present disclosure. FIGS. 5A-5C illustrate views of various stages of forming a semiconductor structure in accordance with one or more implementations described herein. Although FIG. 4 is described in relation to the method 400, the structures disclosed in FIGS. 5A-5C are not limited to the method 400, but instead may stand alone as structures that are independent of the method 400. Similarly, although the method 400 is described in relation to FIGS. 5A-C, the method 400 is not limited to the structures disclosed in FIGS. 5A-5C but instead may stand alone independent of the structures disclosed in FIG. 4. It should be understood that FIGS. 5A-5C illustrates only partial schematic views of a semiconductor device structure 500, and the semiconductor device structure 500 may contain any number of transistor sections and additional materials having aspects as illustrated in the figures. It should also be noted that although the method 400 illustrated in FIG. 4 is described sequentially, other process sequences that include one or more operations that have been omitted and/or added, and/or has been rearranged in another desirable order, fall within the scope of the implementations of the disclosure provided herein.

At operation 410, a substrate stack 504 is received. The substrate stack 504 may be positioned on the substrate support 112 of the plasma processing system 100 shown in FIG. 1. The substrate stack 504 may be or include the substrate 114 shown in FIG. 1. Referring to FIG. 5A, the substrate stack 504 includes the dielectric layer 308. The substrate stack 504 may further include the substrate 312. The substrate stack 504 can include additional layers and/or features, which are not shown for the sake of brevity.

At operation 420, the dielectric layer 308 is exposed to a high-density plasma nitridation process as shown in FIG. 5A, a high-density plasma oxidation process as shown in FIG. 5B, or both a high-density plasma nitridation process and a high-density plasma oxidation process to form a nitrided/oxidized dielectric layer 508 shown in FIG. 5C. In some implementations where both the high-density plasma nitridation process and the high-density plasma oxidation process are performed, the high-density plasma nitridation process and the high-density plasma oxidation process are performed sequentially, for example, the high-density plasma nitridation process is performed first followed by the high-density plasma oxidation process or the high-density plasma oxidation process is performed first followed by the high-density plasma nitridation process. In other implementations, the high-density plasma nitridation process and the high-density plasma oxidation process are performed simultaneously such that the high-density plasma nitridation process and the high-density plasma oxidation process at least partially overlap.

Referring to FIG. 1, in some implementations, where operation 420 includes the high-density plasma nitridation process to incorporate nitrogen into the dielectric layer 308, when utilizing the plasma processing system 100 disclosed herein, a plasma including the first radical is formed in the active zone 172 of the plasma source interior 125. For example, the gas injection insert 140 can introduce a first process gas including nitrogen via the gas injection channels 151 to form the plasma including the first radical. The plasma can be an inductively coupled plasma generated within the gas injection channels 151 by the induction coil 130. The plasma can be can be a decoupled plasma nitridation process (DPN) process. The first process gas can be selected from diatomic nitrogen (N2), ammonia (NH3), or mixtures thereof. In some implementations, the first process gas can be introduced to the active zone 172 of the plasma source interior 125 at a first process gas flow rate in a range from about 1,000 standard cubic centimeters per minute (sccm) to about 10,000 sccm, for example, from about 1,000 sccm to about 9,500 sccm, from about 1,500 to about 9,500 sccm, from about 1,500 sccm to about 8,500 sccm, from about 4,000 sccm to about 8,500 sccm, or from about 6,000 sccm to about 8,000 sccm. In some implementations, the first radical can be introduced for a period of time in a range from about 10 seconds (s) to about 500 s, for example, from about 60 s to about 400 s, from about 90 s to about 300 s, or from about 120 s to about 300 s.

The plasma source 120 is configured to flow the plasma including the first radical through the holes 126 in the separation grid 116 (if present) toward the substrate support 112, to treat the substrate 114 or the substrate stack 504 disposed thereon. The plasma source 120 may generate plasma charged particles, for example, ions and electrons, which recombine on the separation grid 116, so that mostly or only neutral plasma species can pass through the separation grid 116 and expose the substrate 114 or the substrate stack 504 to the high-density nitrogen plasma. In one or more embodiments, the plasma includes one or more of N*, N, N2+, or N+. The plasma comprising the at least one nitrogen radical species contacts the top surface 308t of the dielectric layer 308 facing the separation grid 116. The substrate 114 or the substrate stack 504 can be heated using the plurality of lamps 176 located on a second side of the substrate stack 504 opposite the separation grid 116.

In one or more implementations, which can be combined with other implementations, the high-density plasma nitridation process of operation 220 includes exposing the dielectric layer 308 to an additional radical, for example, a hydroxide radical, an argon radical, a hydrogen radical, or a combination thereof. In some implementations, the additional radical can be formed in the active zone 172 of the plasma source interior 125. For example, the gas injection insert 140 can introduce an additional gas including hydrogen, argon, nitrogen, helium, or a mixture thereof into the active zone 172.

The plasma nitridation process of operation 420 may be performed while maintaining a pressure in a range from about 0.1 Torr to about 10 Torr, or in a range from about 0.1 Torr to about 5 Torr, or in a range from about 0.2 Torr to about 5 Torr. In some implementations, the plasma nitridation process of operation 420 may be performed while maintaining a temperature in a range from about 300 °C to about 750 °C, for example, from about 350 °C to about 700 °C, or from about 350 °C to about 650 °C, or from about 550 °C to about 650 °C. In some implementations, the plasma nitridation process of operation 220 may be performed while operating the plasma source at a power in a range from about 5 kW to about 10 kW, for example, from about 5 kW to about 8 kW, from about 6 kW to about 8 kW, or from about 7 kW to about 8 kW.

During the plasma nitridation process of operation 420, a carrier gas, for example, argon, nitrogen, helium, or a combination thereof, can be introduced to the active zone 172 of the plasma source interior 125 at a flow rate in a range from about 5,000 sccm to about 50,000 sccm, for example, from about 5,000 sccm to about 15,000 sccm, or from about 5,000 sccm to about 9,500 sccm, or from about 5,500 to about 9,500 sccm, or from about 5,500 sccm to about 8,500 sccm, or from about 6,000 sccm to about 8,500 sccm, or from about 7,000 sccm to about 8,000 sccm. In one or more embodiments, the total flow of nitrogen and argon is in a range from about 3,000 sccm to about 60,000 sccm, or in a range from about 5,000 sccm to about 50,000 sccm, or in a range from about 10,000 sccm to about 20,000 sccm. In some implementations, the carrier gas can be introduced for a period of time in a range from about 10 seconds (s) to about 500 s, for example, from about 60 s to about 400 s, from about 90 s to about 300 s, or from about 120 s to about 300 s. The carrier gas may facilitate flow of other process gases.

In some implementations, during operation 420, the dielectric layer 308 is exposed to a high-density plasma oxidation process as shown in FIG. 5B to incorporate oxygen into the dielectric layer 308 Exposure to the high-density oxidation process during operation 420 can remove carbon impurities from the dielectric layer 308 through chemical reaction between the carbon impurities and high-density oxygen radicals and passivate oxygen vacancies with the high-density oxygen radicals, which can eventually increase the k-value by increasing crystallinity in the dielectric layer 308 and reduce the leakage current by removing traps. In some implementations, the high-density plasma oxidation process can be performed by exposing the dielectric layer 308 to a second radical, for example, an oxygen radical.

Referring to FIG. 1, in some implementations, where operation 420 includes the high-density plasma oxidation process, when utilizing the plasma processing system 100 disclosed herein, a plasma including the second radical is formed in the active zone 172 of the plasma source interior 125. For example, the gas injection insert 140 can introduce a second process gas including oxygen to form the plasma including the second radical. The plasma can be an inductively coupled plasma generated within the gas injection channels 151 by the induction coil 130. The second process gas can be selected from H₂O, O₂, O₃, H₂O₂, NO₂, N₂O, H2, or mixtures thereof. In some implementations, the second process gas can be introduced to the active zone 172 of the plasma source interior 125 at a second process gas flow rate in a range from about 1,000 standard cubic centimeters per minute (sccm) to about 10,000 sccm, for example, from about 1,000 sccm to about 9,500 sccm, from about 1,500 to about 9,500 sccm, from about 1,500 sccm to about 8,500 sccm, from about 4,000 sccm to about 8,500 sccm, or from about 6,000 sccm to about 8,000 sccm. In some implementations, the second radical can be introduced for a period of time in a range from about 10 seconds (s) to about 500 s, for example, from about 60 s to about 400 s, from about 90 s to about 300 s, or from about 120 s to about 300 s.

The plasma source 120 is configured to flow the plasma including the oxygen radicals through the holes 126 in the separation grid 116 (if present) toward the substrate support 112, to treat the substrate 114 or the substrate stack 504 disposed thereon. In one or more embodiments, the plasma includes one or more of O*, O, O2+, or O+. The plasma source 120 may generate plasma charged particles, for example, ions and electrons, which recombine on the separation grid 116, so that mostly or only neutral plasma species can pass through the separation grid 116 and expose the substrate 114 or the substrate stack 504 to the high-density oxygen plasma. The plasma comprising the at least one oxygen radical species contacts the top surface 308t of the dielectric layer 308 facing the separation grid 116. The substrate 114 or the substrate stack 504 can be heated using the plurality of lamps 176 located on a second side of the substrate stack 504 opposite the separation grid 116.

The high-density oxygen plasma process of operation 420 may be formed while maintaining a pressure in a range from about 1 Torr to about 20 Torr, for example, from about 1 Torr to about 10 Torr, from about 1 Torr to about 8 Torr, or from about 1 Torr to about 5 Torr. In some implementations, the high-density oxygen plasma process of operation 230 is performed at a temperature, which is less than the deposition temperature of the dielectric layer 308 in order to prevent oxidation of any additional layers present in the substrate stack 504. The high-density oxygen plasma process of operation 230 can be performed while maintaining a temperature in a range from about 300 °C to about 750 °C, for example, from about 350 °C to about 700 °C, or from about 350 °C to about 650 °C, or from about 550 °C to about 650 °C. In some implementations, the high-density oxygen plasma process of operation 230 can be performed while operating the plasma source at a power in a range from about 5 kW to about 10 kW, for example, from about 5 kW to about 8 kW, from about 6 kW to about 8 kW, or from about 7 kW to about 8 kW.

During operation 420, a carrier gas, for example, argon, nitrogen, helium, or a combination thereof, can be introduced to the active zone 172 of the plasma source interior 125 at a flow rate in a range from about 5,000 sccm to about 10,000 sccm, for example, from about 5,000 sccm to about 9,500 sccm, or from about 5,500 to about 9,500 sccm, or from about 5,500 sccm to about 8,500 sccm, or from about 6,000 sccm to about 8,500 sccm, or from about 7,000 sccm to about 8,000 sccm. In some implementations, the carrier gas can be introduced for a period of time in a range from about 10 seconds (s) to about 500 s, for example, from about 60 s to about 400 s, from about 90 s to about 300 s, or from about 120 s to about 300 s. The carrier gas may facilitate flow of other process gases.

In one or more embodiments, the second process gas includes oxygen, hydrogen, and argon. In one or more other embodiments, the second process gas includes oxygen and argon. In one or more other embodiments, the second process gas includes oxygen. In one or more embodiments, the total flow of oxygen, argon, and optionally hydrogen is in a range from about 3,000 sccm to about 60,000 sccm, or in a range from about 5,000 sccm to about 50,000 sccm, or in a range from about 10,000 sccm to about 20,000 sccm.

Referring to FIG. 5C, at operation 430, the nitrided/oxidized dielectric layer 508 is exposed to a high-density helium radical treatment process to cure the nitrided/oxidized dielectric layer 508. The high-density helium radical treatment process of operation 430 can be performed similarly to the high-density helium radical treatment process of operation 220. The high-density helium radical treatment process repairs damage from the plasma nitridation/oxidation, for example, to cure the imperfect bonding from the oxidation and/or nitridation of operation 420 and improve the electrical performance of the treated film.

In one or more implementations, the nitridation/oxidation of the dielectric layer 308 of operation 420 and curing the nitrided/oxidized dielectric layer 508 of operation 430 are performed in the same processing chamber, for example, a first processing volume such as the processing volume 111. In one or more other implementations, the nitridation/oxidation of the dielectric layer 308 of operation 420 and curing the nitrided/oxidized dielectric layer 508 are performed in separate processing chambers, for example, a first processing volume such as the processing volume 111 and a second processing volume, which can be similar to the first processing volume. After operation 420 and prior to operation 430, the substrate stack can be transferred from the first processing volume to the second processing volume without exposure to ambient.

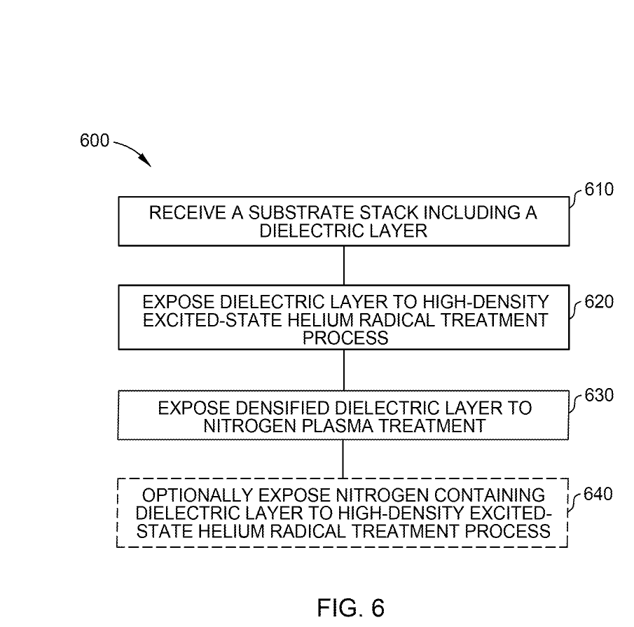

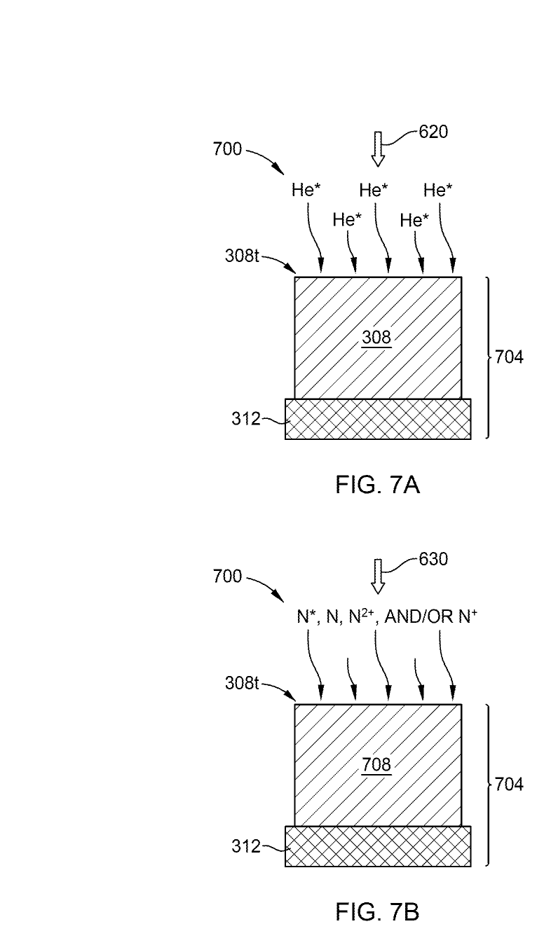

FIG. 6 is a flow diagram depicting a method 600 of treating a dielectric layer with helium radicals in accordance with one or more implementations of the present disclosure. FIGS. 7A-7B illustrate views of various stages of forming a semiconductor structure in accordance with one or more implementations described herein. Although FIG. 6 is described in relation to the method 600, the structures disclosed in FIGS. 7A-7B are not limited to the method 600, but instead may stand alone as structures that are independent of the method 600. Similarly, although the method 600 is described in relation to FIGS. 7A-7B, the method 600 is not limited to the structures disclosed in FIGS. 7A-7B but instead may stand alone independent of the structures disclosed in FIG. 6. It should be understood that FIGS. 7A-7B illustrates only partial schematic views of a semiconductor device structure 700, and the semiconductor device structure 700 may contain any number of transistor sections and additional materials having aspects as illustrated in the figures. It should also be noted that although the method 600 illustrated in FIG. 6 is described sequentially, other process sequences that include one or more operations that have been omitted and/or added, and/or has been rearranged in another desirable order, fall within the scope of the implementations of the disclosure provided herein.

The method 600 is similar to the method 400 except that the high-density helium radical treatment process is performed prior to the high-density plasma nitridation process.

At operation 610, a substrate stack 704 is received. The substrate stack 704 may be positioned on the substrate support 112 of the plasma processing system 100 shown in FIG. 1. The substrate stack 704 may be or include the substrate 114 shown in FIG. 1. Referring to FIG. 7A, the substrate stack 704 includes the dielectric layer 308. The substrate stack 704 may further include the substrate 312. The substrate stack 704 can include additional layers and/or features, which are not shown for the sake of brevity.

At operation 620, as is shown in FIG. 7A, the substrate stack is exposed to a high-density helium radical treatment process to densify the dielectric layer 308 and form a densified dielectric layer 708. The high-density helium radical treatment process of operation 620 can be performed similarly to the high-density helium radical treatment process of operation 220. The high-density helium radical treatment process densifies the dielectric layer 308, for example, a SiOC layer, and reduces the number of Si-CH3 bonds present in the dielectric layer 308 before application of nitrogen plasma during operation 630.

At operation 630, the densified dielectric layer 708 is exposed to a nitridation process to incorporate nitrogen into the densified dielectric layer 708 as a shown in FIG. 7B. The nitridation process of operation 630 may be performed similarly to the high-density plasma nitridation process of operation 420. The nitridation process of operation can include exposing the densified dielectric layer 708 to a nitrogen/argon plasma. In one or more embodiments, the plasma includes one or more of N*, N, N2+, or N+.

Optionally, at operation 640, the nitrided dielectric layer can be exposed to a second high-density helium radical treatment process to cure the nitrided dielectric layer. The second high-density helium radical treatment process of operation 640 can be performed similarly to the high-density helium radical treatment process of operation 220.

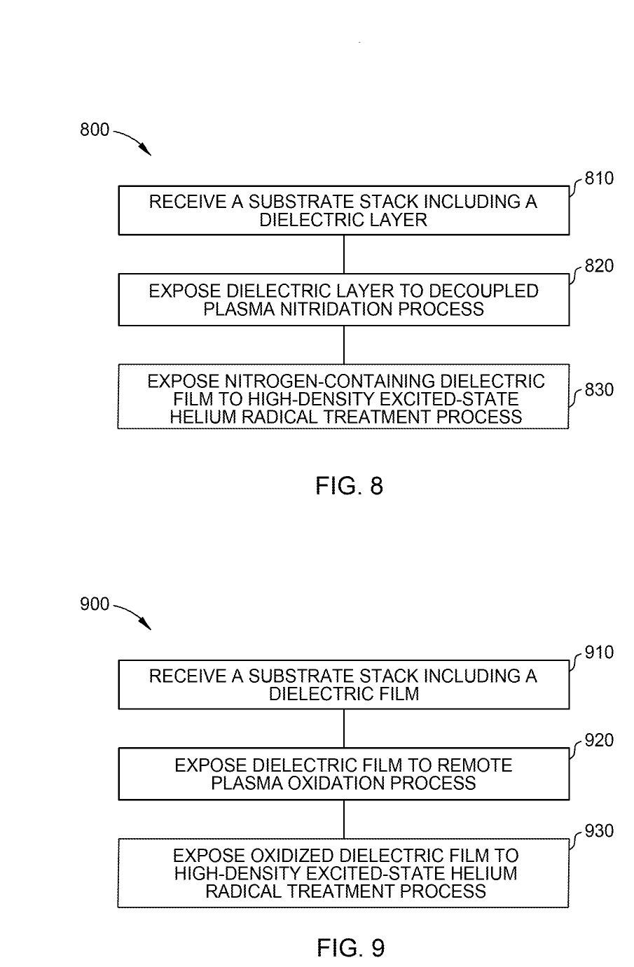

FIG. 8 is a flow diagram depicting another method 800 of performing a helium radical treatment process in accordance with one or more implementations described herein. The method 800 is similar to the method 400 except that the high-density plasma nitridation process of operation 420 is replaced with a decoupled plasma nitridation (DPN) process of operation 820. At operation 810, a substrate stack is received. The substrate stack may be similar to any of the substrate stacks 304, 504, 704. The substrate stack may be positioned on the substrate support of a DPN chamber. The substrate stack includes a dielectric layer, which may be similar to the dielectric layer 308. The substrate stack may further include a substrate, for example, the substrate 312. The substrate stack can include additional layers and/or features, which are not shown for the sake of brevity.

At operation 820, the substrate stack is exposed to a plasma nitridation process to physically incorporate nitrogen into the dielectric layer of the substrate stack to form a nitrided dielectric layer. The plasma nitridation process can be a decoupled plasma nitridation process (DPN). The DPN process infuses the dielectric layer with nitrogen using low-energy, pulsed plasma to create the targeted nitrogen concentration in the dielectric layer. In one or more implementations, during the DPN process, the dielectric layer is bombarded with atomic-N formed by co-flowing N₂ and a noble gas plasma, such as argon. Besides N₂, other nitrogen-containing gases may be used to form the nitrogen plasma, such as NH₃, hydrazines (e.g., N₂H₄ or MeN₂H₃), amines (e.g., Me₃N, Me₂NH or MeNH₂), anilines (e.g., C₆H₅NH₂), and azides (e.g., MeN₃ or Me₃SiN₃). Other noble gases that may be used in a plasma process include helium, neon and xenon. The nitridation process may proceed for a period in a range from about 10 seconds to about 120 seconds, or from about 15 seconds to about 60 seconds, for example, about 30 seconds. The nitridation process may be conducted at a plasma power setting in a range from about 900 watts to about 2,700 watts and at a pressure in a range from about 10 mTorr to about 100 mTorr. In one or more implementations, the nitrogen has a flow rate in a range from about 100 sccm to about 1,000 sccm, while the noble gas has a flow rate in a range from about 100 sccm to about 1,000 sccm. In a particular implementation, the nitridation process is a DPN process and includes a plasma formed by co-flowing Ar and N₂.

At operation 830, the nitrided dielectric layer can be exposed to a high-density helium radical treatment process to cure the nitrided dielectric layer to cure the imperfect bonding from the nitridation of operation 820 and improve the electrical performance of the treated film. The high-density helium radical treatment process of operation 830 can be performed similarly to the high-density helium radical treatment process of operation 220. In one or more implementations, the high-density helium radical treatment process of operation 830 can be performed in the plasma processing system 100. In one or more other implementations, the high-density helium radical treatment process of operation 830 is performed in the same processing chamber as the DPN process of operation 820. In one or more implementations, the high-density helium radical treatment process of operation 830 and the DPN process of operation 820 are performed in separate processing chambers positioned on the same cluster tool such that the substrate stack can be transferred from the DPN process chamber to the plasma processing chamber without exposure to ambient.

FIG. 9 is a flow diagram depicting another method 900 of performing a helium radical treatment process in accordance with one or more implementations described herein. The method 900 is similar to the method 400 except that the high-density plasma oxidation process of operation 420 is replaced with a remote plasma oxidation process of operation 920. At operation 910, a substrate stack is received. The substrate stack may be similar to any of the substrate stacks 304, 504, 704. The substrate stack includes a dielectric layer, which may be similar to the dielectric layer 308. The substrate stack may further include a substrate, for example, the substrate 312. The substrate stack can include additional layers and/or features, which are not shown for the sake of brevity.

At operation 920, the substrate stack is exposed to a plasma oxidation process that physically incorporates oxygen into the dielectric layer of the substrate stack to form an oxidized dielectric layer. The oxidation process can be a remote plasma oxidation (RPO) process. The RPO process includes forming a plasma of an inert gas using a remote plasma source. The plasma gas includes one or more noble gases, such as argon, helium, neon, xenon, krypton, or a combination thereof. In one or more implementations, the plasma gas is argon. A first gas radical is produced by flowing a first gas such as a reactive gas mixture, for example, argon, oxygen, hydrogen or any combination thereof, through the plasma remote source to produce radicals of the first gas via interaction with a plasma. The radicals are introduced, via a plasma conduit, into a processing chamber to incorporate oxygen into the dielectric layer of the substrate stack.

At operation 930, the oxidized dielectric layer can be exposed to a high-density helium radical treatment process to cure the oxidized dielectric layer to cure the imperfect bonding from the oxidation of operation 930 and improve the electrical performance of the treated film. The high-density helium radical treatment process of operation 930 can be performed similarly to the high-density helium radical treatment process of operation 220. In one or more implementations, the high-density helium radical treatment process of operation 930 can be performed in the plasma processing system 100. In one or more other implementations, the high-density helium radical treatment process of operation 930 is performed in the same processing chamber as the RPO process of operation 920. In one or more implementations, the high-density helium radical treatment process of operation 930 and the RPO process of operation 920 are performed in separate processing chambers positioned on the same cluster tool such that the substrate stack can be transferred from the RPO process chamber to the plasma processing chamber without exposure to ambient.

### EXAMPLES

The following non-limiting examples are provided to further illustrate embodiments described herein. However, the examples are not intended to be all inclusive and are not intended to limit the scope of the implementations described herein.

### Example 1

Low-k film treatment: BLACK DIAMOND® (BD, SiOC:H) low-k film was treated with a helium radical curing process as described herein and compared to a BLACK DIAMOND® low-k film treated with a traditional UV curing process. The low-k BD film treated with the helium radical curing process demonstrated a lower k-value and increased hardness relative to the low-k BD film treated with the traditional UV curing process. Not to be bound by theory but it is believed that the helium radical treatment provides energy to increase the amount of carbon bonding with silicon in the film.

### Example 2

PE-ALD oxide densification: A silicon oxide film was deposited using a plasma enhanced ALD process. The silicon oxide film was etched to form a high-aspect-ratio (HAR) structure having an aspect ratio of approximately 40:1. The HAR structure was exposed to the helium radical curing process described herein at 8 kW for approximately ten minutes at 650 °C to densify the HAR structure. The densified HAR structure exhibited a decreased WER of less than six nm/minute relative to the untreated HAR structure.

### Example 3

SiCON inner spacer gapfill treatment for GAA structure: The objective was to incorporate nitrogen into a SiOC film to provide downstream ashing and wet etch resistance. Nitrogen incorporation typically comes with carbon loss and film quality degradation, which increases the WER. Not to be bound by theory but it is believe that the initial SiOC film prior to nitrogen incorporation had too many Si-CH3 bonds and direct application of N2/Ar plasma or NH3/Ar plasma without prior helium radical treatment removes a significant amount of carbon from the film while nitrogen is incorporated. It was found that application of the helium radical treatment process described herein prior to nitrogen incorporation reduced the number of Si-CH3 bonds in the SiOC film before incorporation of nitrogen via the N2/Ar or NH3/Ar plasma, which produced a SiCON film with improved film quality and a decreased WER.

### Example 4

PNA of SiO2: 20 Å of SiO2 film was formed via a rapid thermal oxidation (RTO) followed by nitridation of the SiO2 film via a decoupled plasma nitridation process to form a SiON film. A first sample of the SiON film was exposed to a traditional post nitridation anneal (PNA) process performed at 1,000 °C for 10 seconds at 50 T. A second sample of the SiON film was exposed helium radical treatment process performed at 500 °C for 5 minutes at 8kW and 0.5 Torr. XPS spectrum data indicated that the helium radical treatment performed at 500 °C provided a similar reduction in N=O bonding relative to the PNA treatment performed at 1,000 °C.

The previously described implementations of the present disclosure have many advantages. However, the present disclosure does not necessitate that all the advantageous features and all the advantages need to be incorporated into every implementation of the present disclosure. The helium radical treatment process described herein provides a high flux of highly excited-state He* radicals, which can be used to cure a film post nitridation and/or post oxidation at lower temperatures. The high-density hot He* radical treatment process provides several advantages. The high-density hot He* radical treatment process provides a high-energy treatment that is conformal as opposed to directional. In addition, helium has the smallest atomic radius and is highly diffusive. Further, helium is chemically inert and can be used to treat all types of films at low temperatures. Furthermore, helium radical treatment of low-k dielectric materials, for example, silicon oxide, performed using the plasma processing apparatus and method of the present disclosure improves film quality of the low-k dielectric layer and decreases leakage thereof compared to non-treated films. Moreover, post wet etch sidewall conformality of the treated low-k dielectric layer is improved by a greater degree at lower pressure, namely at 0.5 Torr compared to 2 Torr.

In the Summary and in the Detailed Description, and the Claims, and in the accompanying drawings, reference is made to particular features (including method operations) of the present disclosure. It is to be understood that the disclosure in this specification includes all possible combinations of such particular features. For example, where a particular feature is disclosed in the context of a particular aspect, implementation, implementation, or example of the present disclosure, or a particular claim, that feature can also be used, to the extent possible in combination with and/or in the context of other particular aspects and implementations of the present disclosure, and in the present disclosure generally.

Implementations and all of the functional operations described in this specification can be implemented in digital electronic circuitry, or in computer software, firmware, or hardware, including the structural means disclosed in this specification and structural equivalents thereof, or in combinations of them. Implementations described herein can be implemented as one or more non-transitory computer program products, i.e., one or more computer programs tangibly embodied in a machine readable storage device, for execution by, or to control the operation of, data processing apparatus, e.g., a programmable processor, a computer, or multiple processors or computers.

The processes and logic flows described in this specification can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application specific integrated circuit).

The term “data processing apparatus” encompasses all apparatus, devices, and machines for processing data, including by way of example a programmable processor, a computer, or multiple processors or computers. The apparatus can include, in addition to hardware, code that creates an execution environment for the computer program in question, e.g., code that constitutes processor firmware, a protocol stack, a database management system, an operating system, or a combination of one or more of them. Processors suitable for the execution of a computer program include, by way of example, both general and special purpose microprocessors, and any one or more processors of any kind of digital computer.

Computer readable media suitable for storing computer program instructions and data include all forms of nonvolatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks. The processor and the memory can be supplemented by, or incorporated in, special purpose logic circuitry.

The term “comprises” and grammatical equivalents thereof are used herein to mean that other components, ingredients, operations, etc. are optionally present. For example, an article “comprising” (or “which comprises”) components A, B, and C can consist of (i.e., contain only) components A, B, and C, or can contain not only components A, B, and C but also one or more other components. In addition, whenever a composition, an element or a group of elements is preceded with the transitional phrase “comprising” or grammatical equivalents thereof, it is understood that it is contemplated that the same composition or group of elements may be preceded with transitional phrases “consisting essentially of,” “consisting of,” “selected from the group of consisting of,” or “is” preceding the recitation of the composition, element, or elements and vice versa.

Where reference is made herein to a method comprising two or more defined operations, the defined operations can be carried out in any order or simultaneously (except where the context excludes that possibility), and the method can include one or more other operations which are carried out before any of the defined operations, between two of the defined operations, or after all of the defined operations (except where the context excludes that possibility).

When introducing elements of the present disclosure or exemplary aspects or implementation(s) thereof, the articles “a,” “an,” “the” and “said” are intended to mean that there are one or more of the elements.

The terms “comprising,” “including” and “having” are intended to be inclusive and mean that there may be additional elements other than the listed elements.

While the foregoing is directed to implementations of the present disclosure, other and further implementations of the disclosure may be devised without departing from the basic scope thereof, and the scope thereof is determined by the claims that follow.

What is claimed is:

1. A method for forming a semiconductor device, comprising:
curing a substrate stack comprising a dielectric film to form a cured substrate stack by exposing the substrate stack to an excited-state helium radical treatment process, comprising:
generating an inductively coupled plasma from a process gas comprising helium, wherein the inductively coupled plasma comprises at least one excited-state helium radical species; and
contacting the inductively coupled plasma comprising the at least one excited-state helium radical species with the substrate stack to cure the substrate stack and form the cured substrate stack, wherein curing the substrate stack is performed at a temperature of 750 degrees Celsius or less.

2. The method of claim 1, wherein the process gas comprising helium comprises at least 95% helium.

3. The method of claim 1, wherein the excited-state helium radical species has an energy of 5 eV or higher.

4. The method of claim 1, wherein generating the inductively coupled plasma is performed at a pressure in a range from about 0.1 Torr to about 5 Torr at a radio frequency power in a range from about 5 kW to about 10 kW.

5. The method of claim 4, wherein the temperature is 500 degrees Celsius or less.

6. The method of claim 1, wherein the dielectric film is formed by an atomic layer deposition (ALD) process or a chemical vapor deposition (CVD) process.

7. The method of claim 1, further comprising exposing the substrate stack to oxygen radicals, nitrogen radicals, or both oxygen radicals and nitrogen radicals prior to curing the substrate stack.

8. The method of claim 7, wherein exposing the substrate stack to oxygen radicals, nitrogen radicals, or both oxygen radicals and nitrogen radicals is performed in a first processing volume and curing the substrate stack is performed in a second processing volume.

9. The method of claim 1, wherein the dielectric film is a silicon-containing dielectric film having a k-value of three or less.

10. A method for forming a semiconductor device, comprising:
exposing a substrate stack to oxygen radicals, nitrogen radicals, or both oxygen radicals and nitrogen radicals to form a nitridized/oxidized substrate stack; and
curing the nitridized/oxidized substrate stack to form a cured substrate stack by exposing the nitridized/oxidized substrate stack to an excited-state helium radical treatment process, comprising:
introducing a process gas comprising helium into a gas injection channel of a plasma source;
generating an inductively coupled plasma within the gas injection channel with an induction coil positioned proximate a sidewall of the plasma source and horizontally overlapping the gas injection channel, wherein the inductively coupled plasma comprises at least one excited-state helium radical species; and
contacting the inductively coupled plasma comprising the at least one excited-state helium radical species with the nitridized/oxidized substrate stack to cure the nitridized/oxidized substrate stack and form the cured substrate stack, wherein curing the nitridized/oxidized substrate stack is performed at a temperature of 750 degrees Celsius or less.

11. The method of claim 10, wherein exposing the substrate stack to oxygen radicals, nitrogen radicals, or both oxygen radicals and nitrogen radicals and curing the nitridized/oxidized substrate stack are performed in a first processing volume.

12. The method of claim 10, wherein exposing the substrate stack to oxygen radicals, nitrogen radicals, or both oxygen radicals and nitrogen radicals is performed in a first processing volume and curing the nitridized/oxidized substrate stack is performed in a second processing volume.

13. The method of claim 10, wherein the substrate stack comprises a dielectric film formed by an atomic layer deposition (ALD) process or a chemical vapor deposition (CVD) process.

14. The method of claim 10, wherein the substrate stack comprises a silicon oxide film, a SiOC film, or a silicon nitride film.

15. The method of claim 10, wherein the gas injection channel is defined between a gas injection insert and the sidewall of the plasma source.

16. A plasma processing system, comprising:
a processing chamber defining a processing volume;
a plasma source;
a gas injection channel;
an induction coil positioned proximate to a sidewall of the plasma source and horizontally overlapping the gas injection channel; and
a system controller, comprising:
a memory for storing computer readable instructions; and
a processor coupled to the memory, the processor configured by the computer readable instructions that when executed by the processor perform a plurality of operations including an excited-state helium radical treatment process comprising:
introducing a process gas into the gas injection channel;
generating an inductively coupled plasma within the gas injection channel with the induction coil, wherein the plasma comprises at least one helium radical species;
delivering the plasma from the plasma source to the processing volume; and
processing a substrate stack within the processing volume, the substrate stack comprising a dielectric layer, wherein processing the substrate stack comprises:
contacting the plasma comprising the at least one helium radical species with the dielectric layer, wherein the excited-state helium radical treatment process is performed at a temperature of 750 degrees Celsius or less.

17. The plasma processing system of claim 16, wherein the plurality of operations further comprise exposing the dielectric layer to oxygen radicals, nitrogen radicals, or both oxygen radicals and nitrogen radicals.

18. The plasma processing system of claim 17, wherein exposing the dielectric layer to oxygen radicals, nitrogen radicals, or both oxygen radicals and nitrogen radicals occurs prior to the excited-state helium radical treatment process.

19. The plasma processing system of claim 17, wherein exposing the dielectric layer to oxygen radicals, nitrogen radicals, or both oxygen radicals and nitrogen radicals occurs after the excited-state helium radical treatment process.

20. The plasma processing system of claim 17, further comprising a gas injection insert disposed within the plasma source, wherein the gas injection channel is defined between the gas injection insert and the sidewall of the plasma source.
